(19) United States
(12) Patent Application Publication
(10) Pub. No.: US 2005/0217569 A1
(43) Pub. Date: Oct. 6, 2005

(54) Methods of depositing an elemental silicon-comprising material over a semiconductor substrate and methods of cleaning an internal wall of a chamber

(76) Inventors: Nirmal Ramaswamy, Boise, ID (US); Eric R. Blomiley, Boise, ID (US); Joel A. Drewes, Boise, ID (US)

Correspondence Address: WELLS ST. JOHN P.S., 601 W. FIRST AVENUE, SUITE 1300, SPOKANE, WA, 99201, US

(21) Appl. No.: 10/816,772

(22) Filed: Apr. 1, 2004

(51) Int. Cl. C30B 23/00; C30B 25/00; C30B 28/12; C30B 28/14; G01J 5/02

(52) U.S. Cl. 117/105

(57) ABSTRACT

The invention includes methods of depositing elemental silicon-comprising materials over a semiconductor substrate, and methods of cleaning an internal wall of a chamber. In one implementation, a semiconductor substrate is positioned within a chamber for deposition. The chamber comprises an infrared radiation transparent wall. An elemental silicon-comprising material is deposited on the semiconductor substrate. During such depositing, a deposit is formed on the infrared radiation transparent wall within the chamber. After such depositing, a plasma is generated within the chamber with a cleaning gas from at least one plasma generating electrode received external of the chamber proximate the infrared radiation transparent wall effective to remove at least some of the deposit from the infrared radiation transparent wall within the chamber. Other aspects and implementations are contemplated.

### TECHNICAL FIELD

This invention relates to methods of depositing elemental silicon-comprising materials over a semiconductor substrate, and to methods of cleaning an internal wall of a chamber.

### BACKGROUND OF THE INVENTION

Integrated circuitry fabrication includes deposition of material and layers over a substrate. One or more substrates are received within a deposition chamber within which deposition typically occurs. One or more precursors or substances are caused to flow to the substrate, typically as a vapor, to effect deposition of a layer over the substrate. A single substrate is typically positioned or supported for deposition by a susceptor. In the context of this document, a “susceptor” is any device which holds or supports at least one wafer within a chamber or environment for deposition. Deposition may occur by chemical vapor deposition, atomic layer deposition and/or by other means.

FIGS. 1 and 2 diagrammatically depict a prior art susceptor 110, and issues associated therewith which motivated some aspects of the invention. Susceptor 110 comprises a body 112 which receives a substrate 114 for deposition. Substrate 114 is received within a pocket or recess 116 of susceptor body 112 to elevationally and laterally retain substrate 114 in the desired position.

A particular exemplary system which motivated some of the inventive susceptor designs herein was a lamp heated, thermal deposition system having front and back side radiant heating of the substrate and susceptor for attaining desired temperature during deposition. FIG. 2 depicts a thermal deposition system having at least two radiant heating sources for each side of susceptor 110. Depicted are front side and back side peripheral radiation emitting sources 118 and 120, respectively, and front side and back side radially inner radiation emitting sources 122 and 124, respectively. Incident radiation from sources 118, 120, 122 and 124 typically overlap one another on the susceptor and substrate, creating overlap areas 125. Such can cause an annular region of the substrate corresponding in position to overlap areas 125 to be hotter than other areas of the substrate not so overlapped. Further, the center and periphery of the substrate can be cooler than even the substrate area which is not overlapped due to less than complete or even exposure to the incident radiation.

The susceptor is typically caused to rotate during deposition, with deposition precursor gas flows occurring along arrows “A” from one edge of the wafer, over the wafer and to the opposite side where such is exhausted from the chamber. Arrow “B” depicts a typical H₂ gas curtain within the chamber proximate a slit valve through which the substrate is moved into and out of the chamber. A preheat ring (not shown) is typically received about the susceptor, and provides another heat source which heats the gas flowing within the deposition chamber to the wafer along arrows A and B. However even so, the periphery of the substrate proximate where arrows A and B indicate gas flowing to the substrate is cooler than the central portion and the right-depicted portion of the substrate where the gas exits.

Additionally, robotic arms are typically used to position substrate 114 within recess 116. Such positioning of substrate 114 does not always result in the substrate being positioned entirely within susceptor recess 116. Further, gas flow might dislodge the wafer such that it is received both within and without recess 116. Such can further result in temperature variation across the substrate and, regardless, result in less controlled or uniform deposition over substrate 114.

The above-described system can be used for silicon deposition, including amorphous, monocrystalline and polycrystalline silicon, as well as deposition of silicon mixed with other materials such as a Si—Ge composition in any of crystalline and amorphous forms. Certain aspects of the invention were motivated relative to issues associated with selective epitaxial silicon deposition. In such deposition, a substrate to be deposited upon includes outwardly exposed elemental silicon containing surfaces as well as surfaces not containing silicon in elemental form. During a selective epitaxial silicon deposition, the silicon will preferentially/selectively grow typically only over the silicon surfaces and not the non-silicon surfaces. In many instances, near infinite selectivity is attained, at least for the typical thickness levels at which the selective epitaxial silicon is deposited or grown.

An exemplary prior art method for depositing selective epitaxial silicon includes flows of dichlorosilane at from 50 sccm to 500 sccm, HCl at from 50 sccm to 300 sccm and H₂ at from 3 slm to 40 sim. An exemplary preferred temperature range is from 750° C. to 1,050° C., with 850° C. being a specific example. An exemplary pressure range is from 5 Torr to 100 Torr, with 30 Torr being a specific example. Certain aspects of the invention also encompass selective epitaxial silicon-comprising deposition using the just-described prior art process (preferred), as well as other existing or yet-to-be developed methods.

An exemplary prior art susceptor comprises graphite completely coated with a thin layer (75 microns) of SiC. Such graphite typically has a thermal conductivity of from 180-200 W/mK, while that of SiC is about 250 W/mK. Unfortunately, a selective epitaxial silicon process such as described above will also deposit upon silicon carbide in addition to elemental form silicon. Accordingly, the susceptor also gets deposited upon during a selective epitaxial silicon deposition over regions of a substrate desired to be deposited upon received by the susceptor. This is undesirable at least for purposes of temperature control of the substrate during deposition.

For example, consider that the deposition chamber used in the above-described processing includes upper and lower transparent domes or chamber walls which in part define the internal chamber volume within which deposition occurs. Such domes/walls are transparent to incident infrared radiation, with the lamps which heat the susceptor and substrate being received external of the chamber and domes, with light passing therethrough to provide desired temperature during the deposition. Further, temperature control typically includes the sensing of the temperature of the back side of the susceptor using optical pyrometry techniques. For example, such comprises a non-contacting temperature sensing whereby a sensor received externally of the lower dome is directed to the back side of the susceptor and measures emissivity therefrom and from which the temperature of the susceptor and substrate are derived. However with the back side-growing silicon being of a different material than that of the underlying susceptor, such affects the emission/absorption characteristics of the thermal energy. Such tends to affect the sensing of the susceptor temperature to be reported lower than it actually is. Therefore as a silicon coating builds upon the back side of the susceptor, more energy is typically added to the heat lamps which undesirably increases the substrate temperature in a manner which is difficult to control. In other words, where the optical properties of the susceptor back side change where temperature is being sensed or measured, the measured temperature also changes as well although the temperature of the susceptor might essentially be the same as before the back side coating.

With the above just-described configuration, drift in process control can occur after processing from only 1 to 4 wafers. The accumulated silicon on the susceptor back side has caused a temperature drift of from 1° C. to 2° C. In order to maintain repeatability from wafer to wafer, present methods of contending with the same include a between wafer chamber dry-clean to etch the susceptor, as well as re-depositing a small amount of silicon on the susceptor to provide an initial uniform surface. Such processing can take about as long as processing a single wafer alone, and accordingly reduces throughput by about 50 percent. Yet without re-establishing the chamber to a similar baseline condition, wafer repeatability in the selective silicon deposition is poor.

Another issue with existing and anticipated elemental silicon-comprising deposition systems concerns the upper and lower transparent walls. The inner surfaces of such domes are, of course, exposed to the precursor gases during deposition over the substrate. During processing, a film deposits over the transparent domes, typically comprising silicon but not necessarily elemental-form silicon. Regardless, the layer tends to occlude the transparent nature of the sidewalls, adversely affecting one or both of heat transfer from the external lamps or temperature sensing measurements via optical pyrometry. The internal clouding of the walls is rather slow, but does reach a point at about an interval of processing 15,000 wafers which requires that these domes be cleaned. The whole system is typically shut down, taken apart and cleaned, with the domes being cleaned with HCI to remove the material which has clouded the domes.

A typical silicon-comprising deposition system employs multiple deposition chambers for simultaneously working or depositing on different substrates at the same time. A load lock chamber is typically included for passing a substrate from room ambient into the typical subatmospheric, inert atmosphere environment of the elemental silicon-comprising deposition tool. A substrate, as received within the load lock, is subsequently moved therefrom through a transfer chamber and into the respective deposition chambers for deposition thereupon.

The substrates, when exposed to room ambient, typically form a native oxide thereover which is desirably stripped prior to silicon deposition to the substrate. Such is accomplished by a dip of the substrates in a HF bath. Then, the substrates from this bath must be moved into the inert environment of the deposition tool within 20 minutes or so to avoid native oxide from reforming.

It would be desirable to develop improved methods which address at least some of the above-identified problems. However although some aspects of the invention were motivated from this perspective and in conjunction with the above-described reactor and susceptor designs, the invention is in no way so limited. The invention is only limited by the accompanying claims as literally worded, without interpretive or other limiting reference to the specification and drawings, and in accordance with the doctrine of equivalents.

### SUMMARY

The invention includes methods of depositing elemental silicon-comprising materials over a semiconductor substrate, and methods of cleaning an internal wall of a chamber. In one implementation, a semiconductor substrate is positioned within a chamber for deposition. The chamber comprises an infrared radiation transparent wall. An elemental silicon-comprising material is deposited on the semiconductor substrate. During such depositing, a deposit is formed on the infrared radiation transparent wall within the chamber. After such depositing, a plasma is generated within the chamber with a cleaning gas from at least one plasma generating electrode received external of the chamber proximate the infrared radiation transparent wall effective to remove at least some of the deposit from the infrared radiation transparent wall within the chamber.

In one implementation, a method of cleaning an internal wall of a chamber comprises providing at least one plasma generating electrode external of a deposition chamber proximate a chamber wall, with the chamber wall being transparent to infrared radiation. A plasma is generated within the chamber with a cleaning gas from the at least one plasma generating electrode received external of the chamber effective to remove at least some of a deposit from the infrared radiation transparent wall within the chamber.

In one implementation, a method of depositing an elemental silicon-comprising material over a semiconductor substrate comprises positioning a semiconductor substrate within a deposition chamber for deposition of an elemental silicon-comprising material thereon. A cleaning gas is fed to within the deposition chamber effective to remove at least some of any native oxide formed on the semiconductor substrate. After the feeding, an elemental silicon-comprising material is deposited on the semiconductor substrate within the deposition chamber.

In one implementation, a method of depositing an elemental silicon-comprising material over a semiconductor substrate comprises providing a semiconductor substrate within a cleaning chamber. A cleaning gas is fed to within the cleaning chamber effective to remove at least some of any native oxide formed on the semiconductor substrate. After the feeding, the semiconductor substrate is moved from the cleaning chamber through a transfer chamber to a deposition chamber for deposition of an elemental silicon-comprising material thereon. Such moving occurs within an atmosphere inert to oxidation of the semiconductor substrate. After such moving, an elemental silicon-comprising material is deposited on the semiconductor substrate within the deposition chamber.

Other aspects and implementations are contemplated.

### BRIEF DESCRIPTION OF THE DRAWINGS

Preferred embodiments of the invention are described below with reference to the following accompanying drawings.

FIG. 1 is a top view of a prior art susceptor.

FIG. 2 is a diagrammatic section of the FIG. 1 susceptor taken through line 2-2 in FIG. 1.

FIG. 3 is a diagrammatic depiction of a chamber system usable in accordance with methodical aspects of the invention.

FIG. 4 is a view of the FIG. 3 system at a processing step subsequent to that depicted by FIG. 3.

FIG. 5 is a view of an alternate embodiment to that depicted with FIG. 3.

FIG. 6 is a view of another alternate embodiment to that depicted with FIG. 3.

FIG. 7 is a diagrammatic depiction of a substrate being processed in accordance with an aspect of the invention.

FIG. 8 is a view taken subsequent to the processing depicted by FIG. 7.

FIG. 9 is a view taken subsequent to the processing depicted by FIG. 8.

FIG. 10 is a diagrammatic depiction of a substrate being processed in accordance with an aspect of the invention.

FIG. 11 is a view taken subsequent to the processing depicted by FIG. 10.

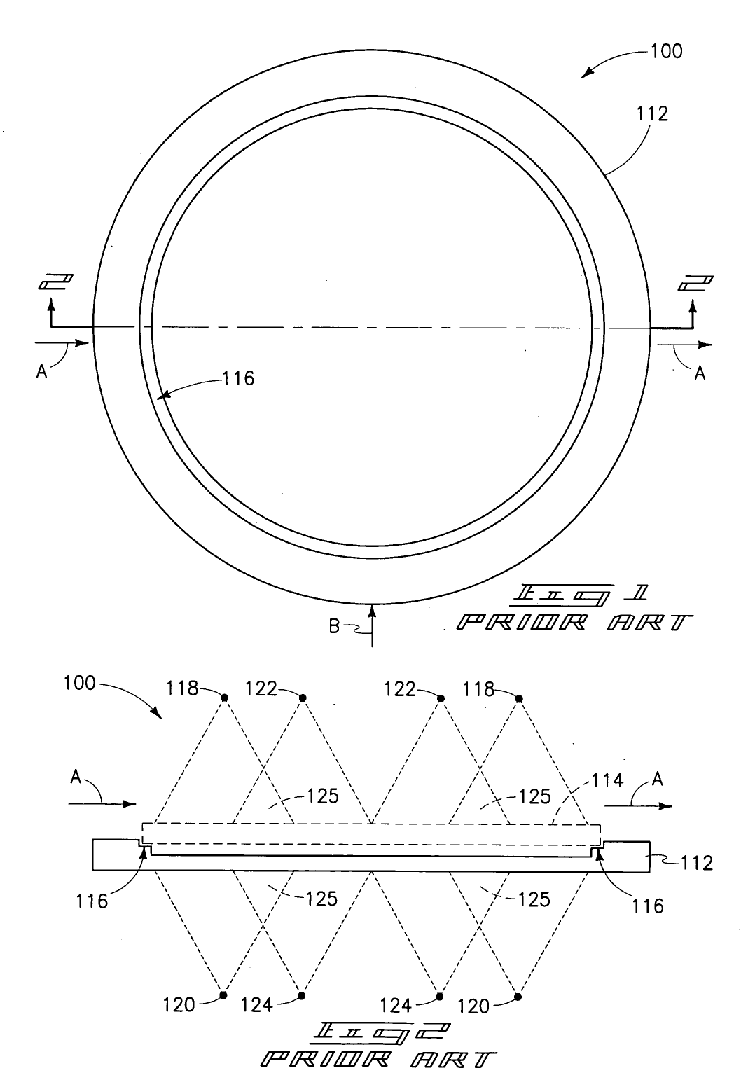

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

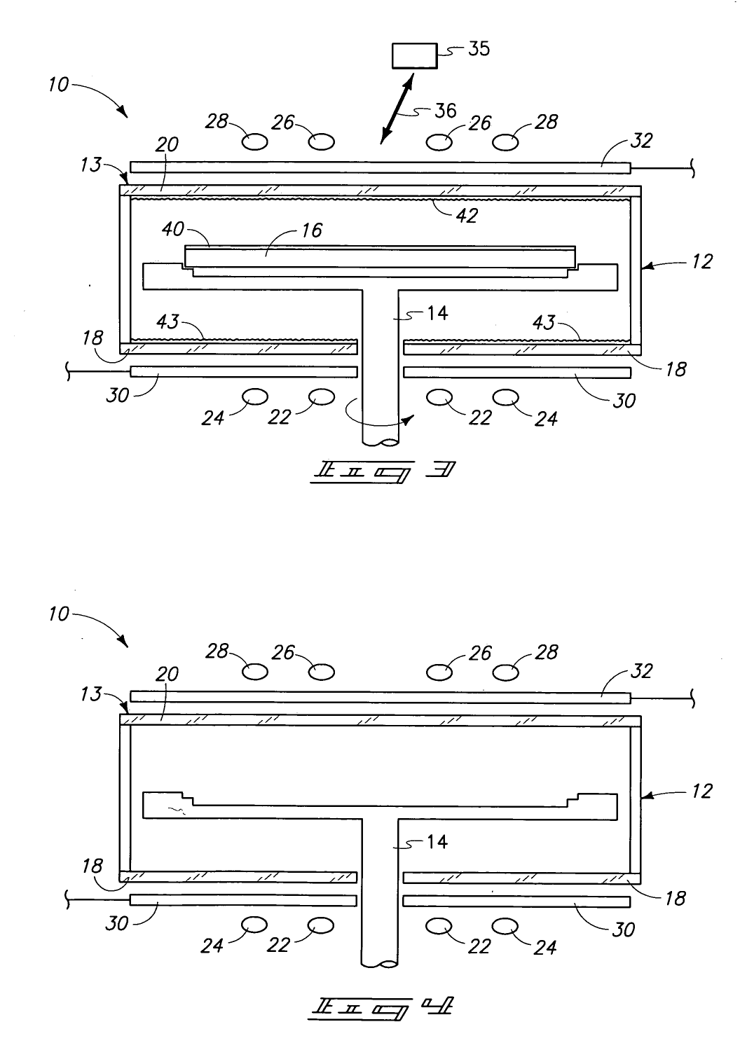

An exemplary method of depositing an elemental silicon-comprising material over a semiconductor substrate is described initially with reference to FIGS. 3 and 4. Such diagrammatically depict a deposition chamber system 10 comprising a chamber 13 having walls 12. A rotatable susceptor 14 retains a semiconductor substrate 16 for deposition within chamber walls 12. Chamber walls 12 comprise first and second infrared radiation transparent walls 18 and 20, respectively. First wall 18 is received below substrate 16, and second wall 20 is received above substrate 16. In the context of this document, a wall which is transparent to infrared radiation passes at least 75% of incident infrared radiation therethrough. By way of example only, exemplary preferred materials include silicon dioxides and sapphire. Further in the context of this document, a “wall” includes all as well as only a portion of any chamber volume defining surface.

At least one lamp is received external of chamber 13 for causing heat flow to semiconductor substrate 16 through first infrared radiation transparent wall 18. FIG. 3 depicts inner lamps 22 and outer lamps 24 received proximate first infrared radiation transparent wall 18. Further in the FIG. 3 depicted embodiment, at least one heating lamp is received external of chamber 13 proximate second infrared radiation transparent wall 20, for example inner lamps 26 and outer lamps 28 in FIG. 3.

At least one plasma generating electrode 30 is received external of chamber 13 proximate second infrared radiation transparent wall 18. In the illustrated and preferred embodiment, at least one plasma generating electrode 32 is received external of chamber 13 proximate first infrared radiation transparent wall 20. The electrodes might be in the form of Rf generating coils, or of other configuration(s). Further in the depicted embodiment, plasma generating electrodes 30 and 32 are received intermediate (between) their respective infrared radiation transparent wall and lamp or lamps. The described system is only exemplary for use in a method of carrying out aspects of the invention, and is only diagrammatic in its representation. Alternate constructions of a chamber or chamber system for carrying out methodical aspects of the invention could of course be utilized, with the concluding method claims not be limited by the depicted or described apparatus unless language literally apparent in the claim under analysis refers to specific apparatus orientation. For example and by way of example only, any of lamps 22, 24, 26 or 28 might be received remotely from the as-shown positions, with light being directed to and through the transparent walls by one or more reflectors, mirrors or by other means. Further by way of example only, the depicted plasma generating electrodes 30 and 32 might be fabricated in such a manner as to be removable when not in use, for example when utilizing heat lamps 22, 24, 26 and 28 in a deposition process not employing any plasma generation with electrodes 30 and 32.

Chamber system 10 is depicted as comprising a non-contacting emissivity sensor 35. FIG. 3 depicts a bold arrow 36 constituting an exemplary path of non-contacting sensing of emissivity to/from sensor 35 relative to substrate 16 through second infrared radiation transparent wall 20.

In one implementation, a method of depositing an elemental silicon-comprising material over a semiconductor substrate comprises positioning a semiconductor substrate within a chamber for deposition. By way of example only, FIG. 3 depicts an exemplary chamber with a semiconductor substrate 16 being so positioned by a susceptor 14. Of course, any means of positioning in any chamber is contemplated in the context of the claims, including existing and yet-to-be developed chambers. An elemental silicon-comprising material 40 is deposited on semiconductor substrate 16 using at least one lamp received external of the chamber as a heat source for flowing heat to the substrate through first infrared radiation transparent wall 18, for example lamps 22 and 24. In one preferred example, the deposited elemental silicon-comprising material 40 is crystalline. Further in one preferred embodiment, the elemental silicon-comprising material comprises selectively deposited epitaxial silicon, including for example silicon-germanium materials such as selectively deposited epitaxial silicon and germanium. Further, semiconductor substrate 16 might remain stationary or, by way of example only, rotate during the depositing.

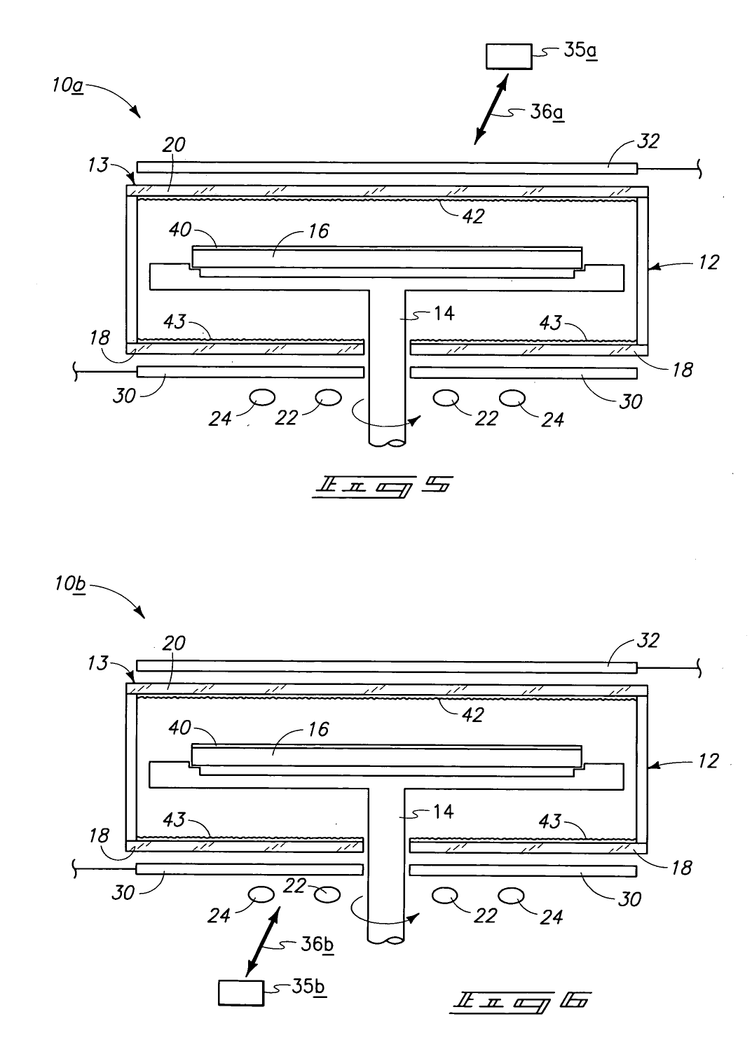

In one exemplary embodiment, no heating lamp might be used during such depositing to flow heat to semiconductor substrate 16 through second infrared radiation transparent wall 20. Alternately, at least one heating lamp received external of chamber 13 for directing radiant heat energy through second infrared radiation transparent wall 20 might be utilized during such depositing, for example lamps 26 and 28. Further for example with respect to an alternate chamber system 10a in FIG. 5, such depicts that no heating lamp is received-external of chamber 13 that would direct heat to second infrared radiation transparent wall 20 during such depositing. In one exemplary embodiment, plasma is not utilized in the stated depositing of an elemental silicon-comprising material, and in one embodiment even if utilized, such is not generated with either of plasma generating electrodes 30 and 32. Alternately, plasma generating electrodes 30 and 32 could be utilized to generate plasma during the deposition.

During the depositing, substrate temperature is detected by measuring emissivity through second infrared radiation transparent wall 20 using a non-contacting emissivity sensor, such as sensor 35. Also during such depositing, a deposit 42 forms on second infrared radiation transparent wall 20 within chamber 13. Further as shown, a deposit 43 forms on first infrared radiation transparent wall 18 within chamber 13.

Deposit 42/43 will typically comprise silicon and, by way of example only, might comprise a polymer, such as a polymer that includes silicon. The deposit, by way of example only, might include combinations of silicon, hydrogen, chlorine, carbon and oxygen. The depicted deposits 42/43 would likely grow during deposition on several different semiconductor substrates within chamber 13, as in the prior art described above.

Referring to FIG. 4, a plasma has been generated within chamber 13 with a cleaning gas from plasma generating electrodes 30 and 32 received external of chamber 13 proximate walls 18 and 20, respectively, to remove at least some of deposits 43 and 42 from walls 18 and 20, respectively. In the depicted preferred FIG. 4 embodiment, such plasma generating occurs while no semiconductor substrate is in the chamber, and also preferably is effective to remove all of the deposit from the associated infrared radiation transparent walls 18 and 20. The preferred cleaning gas preferably comprises a halogen, for example chlorine and/or fluorine. Specific examples include Cl₂ and NF₃. Further more specific preferred examples comprise a cleaning gas chemistry of Cl₂, H₂ and Ar, as well as a cleaning gas chemistry of NF₃, H₂ and Ar. Substrate temperature, chamber pressure and power for the plasma electrodes can be selected by the artisan. By way of example only, exemplary ranges for these parameters include a substrate temperature from about 100° C. to about 600° C., chamber pressure from about 5 Torr to about 60 Torr, and plasma power from about 50W to about 400W.

Next generation elemental silicon-comprising deposition systems might use only bottom side heating lamps for heating the substrate (with no lamps on the top side) for potential better temperature control of the susceptor and substrate, for example as shown in FIG. 5. FIG. 6 illustrates an alternate such exemplary embodiment 10b for use in methodical aspects of the invention. Like numerals from the first described embodiment are utilized where appropriate, with differences being indicated with the suffix “b”. FIG. 6 differs from FIG. 5 in showing temperature sensing occurring from a non-contacting emissivity sensor 35b received below semiconductor substrate 16 having a non-contacting emissivity detecting path 36b for sensing emissivity through first transparent wall 18.

The above-described preferred embodiments depict a pair of transparent walls or wall portions 18 and 20, with each employing heat lamps and a plasma generating electrode. Of course, not all of these components are required to be received proximate the respective transparent wall portions, with the invention only being limited by the accompanying claims as literally worded and in accordance with the doctrine of equivalents. Further, the invention contemplates a multiple of more than two infrared radiation transparent walls, with some or all of said walls having at least one plasma generating electrode received external of the chamber proximate thereto and from which plasma is generated during the plasma generating with the cleaning gas.

Further, the invention contemplates use of a single infrared radiation transparent wall through which heat flows to the substrate from at least one lamp received externally of the chamber. For example and by way of example only, such a method of depositing an elemental silicon-comprising material over a semiconductor substrate comprises positioning such substrate within such a chamber having at least one infrared radiation transparent wall. An elemental silicon-comprising material is deposited on the semiconductor substrate using said at least one lamp received external of the chamber as a heat source. During such depositing, a deposit forms on the infrared radiation transparent wall within the chamber. After such depositing, a plasma is generated within the chamber with the cleaning gas from at least one plasma generating electrode received external of the chamber proximate the infrared radiation transparent wall effective to remove at least some of the deposit from the infrared radiation transparent wall within the chamber. Typical and preferred attributes are otherwise as described above with respect to the first-described embodiments.

Further by way of example only, the invention contemplates a method of depositing an elemental silicon-comprising material over a semiconductor substrate independent of whether heat lamps are utilized to flow heat through an infrared radiation transparent wall. For example, aspects of the invention contemplate positioning a semiconductor substrate within a chamber for deposition, where the chamber includes an infrared radiation transparent wall. An elemental silicon-comprising material is deposited on the semiconductor substrate. During such depositing, a deposit forms on the infrared radiation transparent wall within the chamber, and independent of whether the depositing occurs by lamp generated radiant heat transfer through the transparent wall. Regardless after such depositing, a plasma is generated within the chamber with a cleaning gas from at least one plasma generating electrode received external of the chamber proximate the infrared radiation transparent wall effective to remove at least some of the deposit from the infrared radiation transparent wall within the chamber. Typical and preferred attributes are otherwise as described above in connection with the first-described embodiments.

Further, independent of a method of depositing the elemental silicon-comprising material over a semiconductor substrate, the invention contemplates a method of cleaning an internal wall of a deposition chamber. Such method comprises providing at least one plasma generating electrode external of the deposition chamber proximate a chamber wall, where the chamber wall is transparent to infrared radiation. A plasma is generated within the chamber with a cleaning gas from the at least one plasma generating electrode received external of the chamber effective to remove at least some of the deposit from the infrared radiation transparent wall within the chamber. Typical and preferred attributes are otherwise as described above. The prior art apparently has cleaned walls of a chamber by plasma generation, but not in or suggestive of the context of the method claims as presented herein.

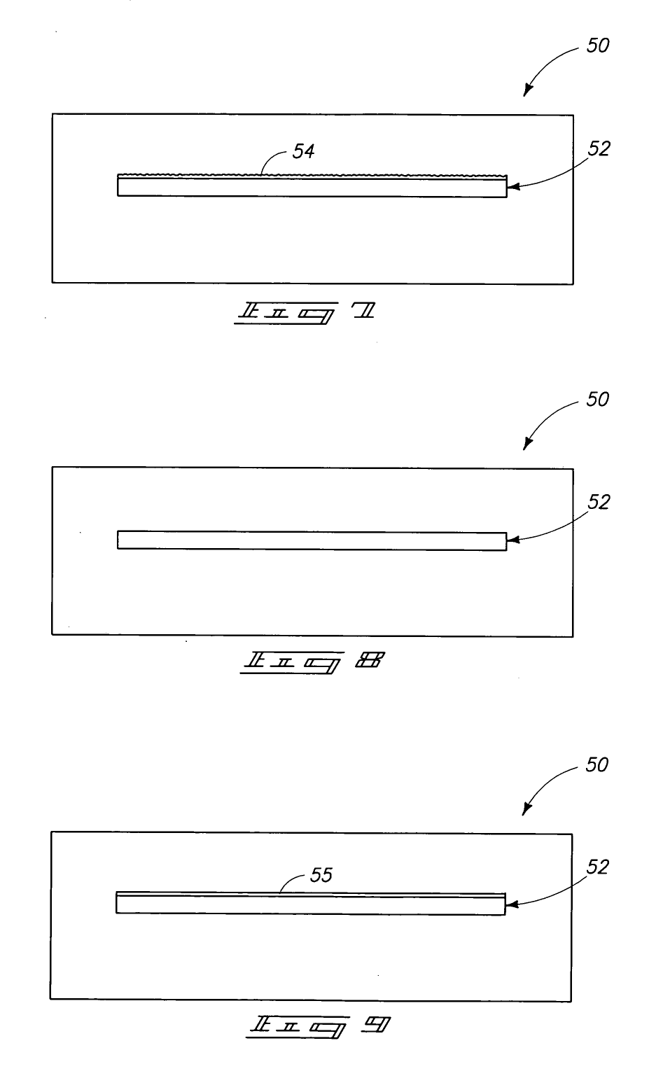

In one implementation, the invention encompasses a method of depositing an elemental silicon-comprising material over a semiconductor substrate. For example referring to FIG. 7, a semiconductor substrate 52 is positioned within a deposition chamber 50 (for example on a susceptor) for the deposition of an elemental silicon-comprising material thereon. FIG. 7 depicts semiconductor substrate 52 comprising some native oxide 54, for example formed by exposure of substrate 52 to room or other ambient prior to positioning within deposition chamber 50, or from exposure to an oxidizing atmosphere within deposition chamber 50. In the depicted embodiment, the subject native oxide 54 is outwardly exposed relative to substrate 52.

Referring to FIG. 8, a cleaning gas has been fed to within deposition chamber 50 effective to remove at least some of any native oxide formed on semiconductor substrate 52. In an exemplary preferred embodiment, all such native oxide 54 from FIG. 7 has been removed in the cleaning gas feeding depicted by FIG. 8. However of course, the invention contemplates removing less than all of any exposed native oxide. Further, the invention contemplates the feeding of a cleaning gas to within a deposition chamber that would be effective to remove at least some of any native oxide which was formed on the semiconductor substrate even in an instance where no appreciable native oxide might have been previously formed. In other words, an aspect of the invention does not require either the formation of a native oxide nor the determination of native oxide formation, with the method including processing where no native oxide might have been formed over the substrate but cleaning gas feeding as just described is conducted regardless.

In preferred embodiments, the cleaning gas comprises a halogen, for example and by way of example, chlorine and/or fluorine. By way of example only, exemplary cleaning gases include HCl, HF, NF₃, ClF₃, and mixtures of any two or more of these materials, as well as any other reactive and inert gases. In one preferred implementation, the cleaning gas comprises a buffer to the rate of oxide removal, thereby reducing the rate of oxide removal than would otherwise occur in the absence of such buffer under otherwise identical conditions. Exemplary preferred buffers comprise carboxylic acids. Preferred carboxylic acids contain only a single carboxylic group, with acetic being one such example. Further in one preferred embodiment, the carboxylic acid comprises CₓH₂ₓ₊₁COOH, where “x” is greater than or equal to 2.

The temperature of the semiconductor substrate during feeding of the cleaning gas is preferably from about 20° C. to about 800° C. Pressure within the deposition chamber during the cleaning gas feeding is preferably atmospheric or subatmospheric. Plasma may or may not be utilized, and whether remote or generated within the chamber.

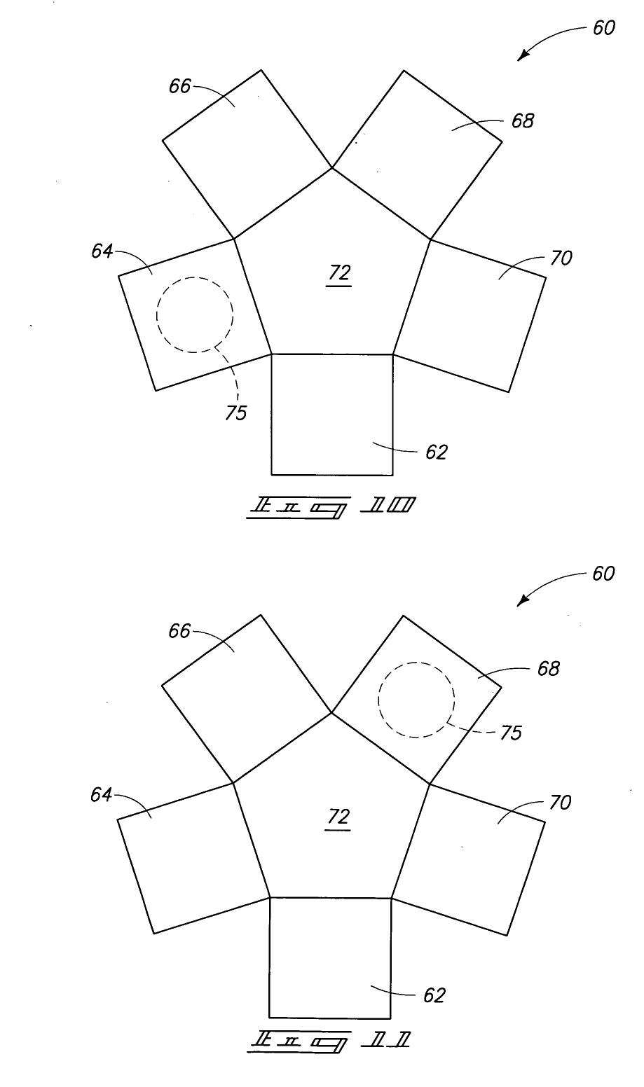

Referring to FIG. 9, after feeding of the cleaning gas, an elemental silicon comprising material 55 is deposited on semiconductor substrate 52 within deposition chamber 50. Exemplary preferred materials are those as described above.

The above processing described but one exemplary implementation of in situ cleaning of at least some native oxide from semiconductor within a deposition chamber within which an elemental silicon-comprising material deposition will occur. By way of example only, FIG. 10 is utilized to describe another method of depositing an elemental silicon-comprising material over a semiconductor substrate. FIG. 10 diagrammatically depicts a deposition tool 60 adapted for depositing elemental silicon-comprising material. Typically, such would be configured for subatmospheric pressure deposition, and is depicted as comprising a load lock chamber 62, a cleaning chamber 64 and three deposition chambers 66, 68 and 70. Of course, more or fewer chambers could be utilized. A preferred transfer chamber 72 is centrally positioned relative to the stated other chambers for transferring substrates among the various chambers in an inert, or at least sealed, environment.

The invention contemplates providing a semiconductor substrate within a cleaning chamber, for example substrate 75 being positioned within cleaning chamber 64. A cleaning gas would be fed to within cleaning chamber 64 effective to remove at least some of any native oxide formed on semiconductor substrate 75.

Referring to FIG. 11, and after the stated feeding, the semiconductor substrate 75 has been moved from cleaning chamber 64 through transfer chamber 72 to a deposition chamber, for example chamber 68, for deposition of an elemental silicon-comprising material thereon. Such moving occurs within an atmosphere which is inert to oxidation of semiconductor substrate 75. After such moving, an elemental silicon-comprising material is deposited on semiconductor substrate 75 within deposition chamber 68. Preferred attributes are otherwise as described above in connection with the immediately described method with respect to FIGS. 7-9.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

1. A method of depositing an elemental silicon-comprising material over a semiconductor substrate, comprising:
positioning a semiconductor substrate within a chamber for deposition, the chamber comprising an infrared radiation transparent wall;
depositing an elemental silicon-comprising material on the semiconductor substrate; during said depositing, forming a deposit on the infrared radiation transparent wall within the chamber; and
after said depositing, generating a plasma within the chamber with a cleaning gas from at least one plasma generating electrode received external of the chamber proximate the infrared radiation transparent wall effective to remove at least some of the deposit from the infrared radiation transparent wall within the chamber.

2. The method of claim 1 comprising multiple infrared radiation transparent walls, each of said walls having at least one plasma generating electrode received external of the chamber proximate thereto and from which plasma in generated during said generating.

3. The method of claim 1 wherein the elemental silicon-comprising material is crystalline.

4. The method of claim 3 wherein the elemental silicon-comprising material comprises selectively deposited epitaxial silicon.

5. The method of claim 4 the selectively deposited epitaxial silicon comprises Ge.

6. The method of claim 1 wherein the deposit comprises silicon.

7. The method of claim 1 wherein the deposit comprises a polymer.

8. The method of claim 7 wherein the deposit comprises silicon.

9. The method of claim 1 wherein the generating removes all of the deposit.

10. The method of claim 1 wherein the generating occurs while no semiconductor substrate is in the chamber.

11. The method of claim 1 wherein the cleaning gas comprises a halogen.

12. The method of claim 11 wherein the halogen comprises chlorine.

13. The method of claim 12 wherein the cleaning gas comprises Cl₂.

14. The method of claim 12 wherein the cleaning gas comprises Cl₂ and H₂.

15. The method of claim 12 wherein the cleaning gas comprises Cl₂, H₂, and Ar.

16. The method of claim 11 wherein the halogen comprises fluorine.

17. The method of claim 16 wherein the cleaning gas comprises NF₃.

18. The method of claim 16 wherein the cleaning gas comprises NF₃ and H₂.

19. The method of claim 16 wherein the cleaning gas comprises NF₃, H₂, and Ar.

20. The method of claim 1 comprising rotating the semiconductor substrate during the depositing.

21. The method of claim 1 wherein no plasma is generated during the depositing.

22. The method of claim 1 wherein plasma is generated during the depositing.

23. The method of claim 22 wherein the plasma generated during the depositing is not generated with said plasma generated electrode received external of the chamber proximate the infrared radiation transparent wall.

24. A method of depositing an elemental silicon-comprising material over a semiconductor substrate, comprising:
positioning a semiconductor substrate within a chamber for deposition, the chamber comprising an infrared radiation transparent wall through which heat flows to the substrate from at least one lamp received external of the chamber;
depositing an elemental silicon-comprising material on the semiconductor substrate using the at least one lamp received external of the chamber as a heat source; during said depositing, forming a deposit on the infrared radiation transparent wall within the chamber; and
after said depositing, generating a plasma within the chamber with a cleaning gas from at least one plasma generating electrode received external of the chamber proximate the infrared radiation transparent wall effective to remove at least some of the deposit from the infrared radiation transparent wall within the chamber.

25. The method of claim 24 comprising during said depositing, detecting substrate temperature by measuring emissivity through the infrared radiation transparent wall using a non-contacting emissivity sensor.

26. The method of claim 24 comprising multiple infrared radiation transparent walls, each of said walls having at least one plasma generating electrode received external of the chamber proximate thereto and from which plasma in generated during said generating.

27. The method of claim 26 wherein each of said walls has at least one lamp received external of the chamber which is used during the depositing as a heat source.

28. The method of claim 24 wherein the at least one plasma generating electrode is received intermediate the infrared transparent wall and the at least one lamp.

29. The method of claim 24 wherein the elemental silicon-comprising material comprises selectively deposited epitaxial silicon.

30. The method of claim 24 wherein the deposit comprises silicon.

31. The method of claim 24 wherein the deposit comprises a polymer.

32. The method of claim 31 wherein the deposit comprises silicon.

33. The method of claim 24 wherein the generating removes all of the deposit.

34. The method of claim 24 wherein the generating occurs while no semiconductor substrate is in the chamber.

35. The method of claim 24 wherein the cleaning gas comprises a halogen.

36. The method of claim 35 wherein the halogen comprises chlorine.

37. The method of claim 36 wherein the cleaning gas comprises Cl₂.

38. The method of claim 35 wherein the halogen comprises fluorine.

39. The method of claim 38 wherein the cleaning gas comprises NF₃.

40. The method of claim 24 wherein no plasma is generated during the depositing.

41. The method of claim 24 wherein plasma is generated during the depositing.

42. The method of claim 41 wherein the plasma generated during the depositing is not generated with said plasma generated electrode received external of the chamber proximate the infrared radiation transparent wall.

43. A method of depositing an elemental silicon-comprising material over a semiconductor substrate, comprising:
positioning a semiconductor substrate within a chamber for deposition, the chamber comprising first and second infrared radiation transparent walls, heat flowing to the substrate through the first infrared radiation transparent wall from at least one lamp received external of the chamber;
depositing an elemental silicon-comprising material on the semiconductor substrate using the at least one lamp received external of the chamber as a heat source;
during said depositing, detecting substrate temperature by measuring emissivity through the second infrared radiation transparent wall using a non-contacting emissivity sensor;
during said depositing, forming a deposit on the second infrared radiation transparent wall within the chamber; and
after said depositing, generating a plasma within the chamber with a cleaning gas from at least one plasma generating electrode received external of the chamber proximate the second infrared radiation transparent wall effective to remove at least some of the deposit from the second infrared radiation transparent wall within the chamber.

44. The method of claim 43 wherein the first infrared radiation transparent wall is received below the positioned substrate.

45. The method of claim 43 wherein the second infrared radiation transparent wall is received above the positioned substrate.

46. The method of claim 43 wherein no heating lamp is received external of the chamber which directs heat to the second infrared radiation transparent wall during said depositing.

47. The method of claim 43 wherein at least one heating lamp is received external of the chamber for directing heat to the second infrared radiation transparent wall.

48. The method of claim 47 wherein the at least one heating lamp for directing heat to the second infrared radiation transparent wall is used during said depositing to flow heat to the substrate through the second infrared radiation transparent wall.

49. The method of claim 43 wherein no heating lamp is used during said depositing to flow heat to the substrate through the second infrared radiation transparent wall.

50. The method of claim 43 wherein,
during said depositing, forming a deposit on the first infrared radiation transparent wall within the chamber; and
at least one plasma generating electrode is received external of the chamber proximate the first infrared radiation transparent wall and from which plasma in generated during said generating and being effective to remove at least some of the deposit from the first infrared radiation transparent wall within the chamber.

51. The method of claim 43 wherein the elemental silicon-comprising material comprises selectively deposited epitaxial silicon.

52. The method of claim 43 wherein the deposit comprises silicon.

53. The method of claim 43 wherein the deposit comprises a polymer.

54. The method of claim 53 wherein the deposit comprises silicon.

55. The method of claim 43 wherein the generating removes all of the deposit.

56. The method of claim 43 wherein the generating occurs while no semiconductor substrate is in the chamber.

57. The method of claim 43 wherein the cleaning gas comprises a halogen.

58. The method of claim 57 wherein the halogen comprises chlorine.

59. The method of claim 58 wherein the cleaning gas comprises Cl₂.

60. The method of claim 57 wherein the halogen comprises fluorine.

61. The method of claim 60 wherein the cleaning gas comprises NF₃.

62. A method of cleaning an internal wall of a chamber, comprising:
providing at least one plasma generating electrode external of a deposition chamber proximate a chamber wall, the chamber wall being transparent to infrared radiation; and
generating a plasma within the chamber with a cleaning gas from the at least one plasma generating electrode received external of the chamber effective to remove at least some of a deposit from the infrared radiation transparent wall within the chamber.

63. The method of claim 62 wherein the deposit comprises a polymer.

64. The method of claim 63 wherein the deposit comprises silicon.

65. The method of claim 62 wherein the generating removes all of the deposit.

66. The method of claim 62 wherein the generating occurs while no semiconductor substrate is in the chamber.

67. The method of claim 62 wherein the cleaning gas comprises a halogen.

68. The method of claim 67 wherein the halogen comprises chlorine.

69. The method of claim 68 wherein the cleaning gas comprises Cl₂.

70. The method of claim 68 wherein the cleaning gas comprises Cl₂ and H₂.

71. The method of claim 68 wherein the cleaning gas comprises Cl₂, H₂, and Ar.

72. The method of claim 67 wherein the halogen comprises fluorine.

73. The method of claim 72 wherein the cleaning gas comprises NF₃.

74. The method of claim 72 wherein the cleaning gas comprises NF₃ and H₂.

75. The method of claim 72 wherein the cleaning gas comprises NF₃, H₂, and Ar.

76. A method of depositing an elemental silicon-comprising material over a semiconductor substrate, comprising:
positioning a semiconductor substrate within a deposition chamber for deposition of an elemental silicon-comprising material thereon;
feeding a cleaning gas to within the deposition chamber effective to remove at least some of any native oxide formed on the semiconductor substrate; and
after the feeding, depositing an elemental silicon-comprising material on the semiconductor substrate within the deposition chamber.

77. The method of claim 76 wherein the elemental silicon-comprising material is crystalline.

78. The method of claim 77 wherein the elemental silicon-comprising material comprises selectively deposited epitaxial silicon.

79. The method of claim 78 the selectively deposited epitaxial silicon comprises Ge.

80. The method of claim 76 wherein the cleaning gas comprises a halogen.

81. The method of claim 80 wherein the halogen comprises chlorine.

82. The method of claim 81 wherein the cleaning gas comprises HCl.

83. The method of claim 80 wherein the halogen comprises fluorine.

84. The method of claim 83 wherein the cleaning gas comprises HF.

85. The method of claim 83 wherein the cleaning gas comprises NF₃.

86. The method of claim 83 wherein the cleaning gas comprises CIF₃.

87. The method of claim 76 wherein the cleaning gas comprises a buffer to rate of oxide removal.

88. The method of claim 87 wherein the buffer comprises a carboxylic acid.

89. The method of claim 88 wherein the carboxylic acid contains only a single carboxylic group.

90. The method of claim 89 wherein the carboxylic acid comprises acetic acid.

91. The method of claim 89 wherein the carboxylic acid comprises CₓH₂ₓ₊₁COOH, where “x” is greater than or equal to 2.

92. The method of claim 76 wherein temperature of the semiconductor substrate during the feeding is from about 20° C. to about 800° C.

93. The method of claim 76 wherein pressure within the deposition chamber is atmospheric during the feeding.

94. The method of claim 76 wherein pressure within the deposition chamber is subatmospheric during the feeding.

95. The method of claim 76 wherein native oxide is formed on the semiconductor substrate prior to the feeding, and at least some of which is removed by the feeding.

96. The method of claim 95 wherein said native oxide is outwardly exposed, the feeding removing all such exposed native oxide.

97. The method of claim 95 wherein said native oxide is formed on the semiconductor substrate prior to the positioning.

98. A method of depositing an elemental silicon-comprising material over a semiconductor substrate, comprising:
providing a semiconductor substrate within a cleaning chamber;
feeding a cleaning gas to within the cleaning chamber effective to remove at least some of any native oxide formed on the semiconductor substrate;
after the feeding, moving the semiconductor substrate from the cleaning chamber through a transfer chamber to a deposition chamber for deposition of an elemental silicon-comprising material thereon, said moving occurring within an atmosphere inert to oxidation of the semiconductor substrate; and
after the moving, depositing an elemental silicon-comprising material on the semiconductor substrate within the deposition chamber.
